(19) United States
(12) Patent Application Publication
(10) Pub. No.: US 2007/0284541 A1
(43) Pub. Date: Dec. 13, 2007

(54) Oxidative cleaning method and apparatus for electron microscopes using UV excitation in a oxygen radical source

(76) Inventor: Ronald A. Vane, Redwood City, CA (US)

Correspondence Address: STORM LLP, BANK OF AMERICA PLAZA, 901 MAIN STREET, SUITE 7100, DALLAS, TX, 75202, US

(21) Appl. No.: 11/449,475

(22) Filed: Jun. 8, 2006

(51) Int. Cl. H01J 37/16

(52) U.S. Cl. 250/441.11; 250/306; 250/307; 250/310; 250/311

(57) ABSTRACT

An improved method and apparatus are provided for cleaning the specimen and interior specimen chamber of Electron Microscopes, and similar electron beam instruments. The apparatus consists of a UV source oxygen-radical generator placed on a specimen chamber port or inside the specimen chamber under vacuum. Air or other oxygen and nitrogen mixture is admitted to the generator at a pressure below 1 Torr. The UV source radiates UV wavelengths below 190 nm that are used to disassociate oxygen to create the oxygen radicals. The oxygen radicals then disperse by convective flow throughout the chamber to clean hydrocarbons from the surfaces of the chamber, stage and specimen by oxidation to volatile oxide gases. The oxide gases are then removed by the convective flow to the vacuum pump.

In particular it is a novel method and apparatus for cleaning the specimen chamber, specimen stage, and specimen inside the vacuum system of these instruments with oxygen radicals produced from air or other oxygen containing gas by photo-dissociation by passing said gas by a UV source with wavelengths that can produce oxygen radicals. The oxygen radicals are used to oxidize the hydrocarbons and convert them to easily pumped gases. The method and apparatus can be added to the analytical instrument and other vacuum chambers with no change to its analytical purpose or design.

### BACKGROUND OF THE INVENTION

1. Field of Invention

The present invention relates to cleaning vacuum chambers and vacuum analytical instruments such as Scanning Electron Microscopes (SEM), Scanning Electron Microprobes, Transmission Electron Microscopes (TEM) and other charge particle beam instruments that are subject to contamination problems from hydrocarbons.

2. Description of Prior Art

Electron microscopy is used to detect, measure, and analyze constituents present in very small areas of materials. Hydrocarbon contaminants adsorbed on the surface or surface films interacting with the incident electron probe beam can distort the results. The distortion may take the form of deposits of polymer in the scanned area, a darkening of the scanned area, a loss of resolution, or other artifacts. Deposits created by the interaction of the probe beam with the surface specimen also may interfere with the probe beam or emitted electrons and x-rays and thus adversely affect accurate analysis. Deposits also add uncertainty to SEM measured line widths for semiconductor device critical dimension metrology. These Hydrocarbons are present in trace levels in ordinary room air and come from living organisms and man-made material. All surfaces exposed to room air at atmospheric pressure accumulate these hydrocarbons. In the semiconductor industry said contamination is known as Atmospheric Molecular Contamination or “AMC”. Reducing and controlling AMC is an active area of concern for semiconductor manufacturers as device dimensions get smaller. Surfaces are further hydrocarbon contaminated by touching, the use of high vapor pressure materials in vacuum system, or in general “poor vacuum practices”.

Another problem is the condensation of pump oils on the windows of the x-ray and electron detectors distorting results. The most serious problem of this type is the absorption of low-energy x-rays from Be, C, N, O and F by oil films which can prevent measurement of these elements by X-ray emission spectroscopy.

Contaminants typically are introduced by one of four ways including on the specimen, on the specimen stage, carried into the chamber by the evacuation system, or are present on the internal components of the instrument. Contaminants introduced from the evacuation system can be reduced by trapping, by purging, or by using cleaner pumps. Once present inside the chamber, these contaminants reside on the chamber surfaces and can be removed only slowly and with low efficiency by the high vacuum pump.

Inorganic specimens (metals, ceramics, semiconductors, etc.) may carry contaminants into the chamber. These may be part of the specimen, residues from sample preparation techniques or be caused by improper sample handling or storage techniques. In addition, clean surfaces will accumulate a surface film of hydrocarbon scum if left exposed to ordinary room air for any length of time. The sources of these hydrocarbons are most any living thing, organic object, or other source of hydrocarbon vapors in the vicinity. While the part of the films created in these processes dissipate under vacuum conditions, a small amount generally remains on surfaces and is sufficient to cause problems when the specimen is subsequently examined in the analytical instruments listed.

These residues are widely distributed and generally are at low concentrations on the various surfaces. Some of the contaminant molecules become mobile in the vacuum environment. At high vacuum the mean free path of molecules once vaporized is comparable to or longer than the dimensions of the vacuum chamber of these instruments. The contaminants move in the vapor phase from surface to surface in the vacuum environment and are attracted to any focused electron probe beam, forming deposits through an ionization and deposition process. Since these contaminants can travel large distances within the vacuum chamber and over the surface of a specimen, it is important to remove or immobilize these species as much as possible prior to an analysis without disturbing the microstructure of the specimen.

Several patents have previously described methods of reducing contamination in electron microscopes. Hahn et al in U.S. Pat. No. 3,148,465 (1968) described a method of immobilizing the Hydrocarbon by exposing it to radiation near the specimen to produce an adsorbing effect on the surrounding surfaces. A device for cleaning electron microscope stages and specimens is described in U.S. Pat. No. 5,510,624 (Zaluzec, 1995) for analytical electron microscopes. That apparatus uses a plasma generating chamber and an airlock to allow the specimen and stages to be placed into the plasma chamber for cleaning. It may be connected with the analytical chamber of the analytical electron microscope. Glow-discharge and plasma cleaning devices and cleaning methods for electron optics are described in U.S. Pat. No. 5,312,519 (Sakai et al.), U.S. Pat. No. 5,539,211 (Ohtoshi et al.) and U.S. Pat. No. 4,665,315 (Bacchetti et al.). These three patents use either direct or remote plasma cleaning to clean the electron optics of the instruments.

Vane disclosed in U.S. Pat. Nos. 6,105,589, 6,452,315, and 6,610,257 the technology used by XEI Scientific, Inc. in the Evactron® De-Contaminator systems that have been sold for cleaning electron microscopes and other vacuum systems since 1999. These patents describe an oxidative cleaning system and apparatus using low powered RF plasma to produce oxygen radicals, an active neutral species, from air to oxidize and remove these hydrocarbons. This plasma excited system works well, but suffers from a Nitrogen ion problem as disclosed in the first patent (U.S. Pat. No. 6,105,589) and solved by using a very low energy plasma and special electrode (U.S. Pat. No. 6,610,257) for dissociation of the oxygen in air. The reaction with oxygen radicals to produce CO, CO₂, H₂O and other volatile oxides such as short chain alcohols and ketones are the most important for the cleaning and removal of hydrocarbons by the vacuum pump. These reaction products are quickly removed as gases from the vacuum system. The ions and electrons produced by the plasma are not needed as the reactive species for hydrocarbon removal. A disadvantage of ions and electrons from the plasma is that they polymerize the hydrocarbons and make them harder to remove. In the absence of nitrogen ions or other reactive species that destroy O radicals, O radicals are long lived and have the ability to do isotropic cleaning on all surfaces in the chamber. Another disadvantage of the Evactron device is that it will not produce O radicals at pressures below 10-4 Torr which keeps the Evactron from cleaning when the instrument is at high vacuum. Another disadvantage is that the plasma produces high levels of free electrons in SEM imaging while the Evactron plasma is operating. (® XEI Scientific, Inc.)

In the operation of the Evactron® systems it was noticed that the UV light from plasma source had a positive effect on the cleaning efficiency of system, thus further investigation was done. It has been well documented that UV light can be used to produce Ozone and then disassociate Ozone to make O radicals for removing semiconductor photo resist and other accumulated reaction products in semiconductor production.(Rhieu U.S. Pat. No. 6,143,477), (Parke U.S. Pat. No. 6,098,637). The usual method is to produce Ozone either by disassociation of Oxygen by electrical discharge, in a plasma, or by UV excitation with wavelengths below 193 nm. The O radicals (O₁ atoms) then react with O₂ to form O₃ Ozone. The production of Ozone is an exothermic chemical reaction and energy is released. It is well known in chemical physics theory that this reaction requires a third body, another molecule or atom, to carry away this extra energy as kinetic energy, or the newly formed ozone molecule will promptly disassociate. As practical matter this means that Ozone is not formed in significant quantities at pressures below about 133 Pa (Pascal) or 1 Torr. Thus to form Oxygen radicals for use in a vacuum system all that is required are pressures below 1 Torr, O₂, and source of energy for disassociation. The Evactron De-Contaminator uses an RF plasma to produce Oxygen radicals. But UV light can also be used to make Oxygen radicals. UV light from 193 nm to 150 nm is strongly absorbed by Oxygen O₂ to produce O radicals. UV light between 220 nm and 240 nm weakly photo disassociates Oxygen.

The use of UV light to excite Oxygen for cleaning and ashing has been done by others. Spill (U.S. Pat. No. 7,005,638) discloses directing an electron beam and UV light beam simultaneous on the specimen surface to reduce contamination. Van Schaik et al (U.S. Pat. No. 6,724,460) uses the interaction of the EUV beam with low concentration of oxygen to produce oxygen radical for cleaning a lithographic projection apparatus. Agarwal (U.S. Pat. No. 6,649,545) discloses using UV lamps to keep active species produced in a upstream plasma active for plasma processing. Rheiu (U.S. Pat. No. 6,143,477) discloses the use of two UV lamps to make Oxygen radicals for cleaning/ashing of semiconductor wafers. The first is used to make Ozone with UV <190 nm and the second (about 250 nm) to disassociate the Ozone to make radicals.

It is an object of the present invention to provide an improved method for cleaning the specimen chamber, specimen stage and a specimen in the vacuum system of an electron microscope or similar analytical instrument using an electron beam such as a scanning electron microprobe instrument or Focused ion beam instrument. It is another object of the present invention to produce more O radicals from air by completely avoiding the production of nitrogen ions. It is another object of the present invention to use single UV lamp and to avoid the production of ozone by using vacuum pressures too low to sustain ozone formation. It is another object of the present invention to produce oxidation and ashing without the need to expose the surfaces or chamber to high intensity UV light or plasma. It is another object of the present invention to provide a method for cleaning said instruments that can be operated at lower pressures than plasma methods thus alleviating the need to raise to pressure to plasma operation pressures, and allow instrument operation during cleaning. It is another object of the present invention to provide a method for cleaning said instruments that does not produce free electrons and ions in a plasma that would interfere with electron detection during instrument operation. It is another object of the present invention to provide a cleaning system that is small and that can be mounted on a standard chamber port of the electron microscope without mechanical interference from other devices and parts of the electron microscope. These improvements results in a cleaning system that is faster and cleans the specimen chamber, stage, and specimen of the analytical instrument better than previous arrangements. The result of a cleaner specimen, specimen chamber and stage is that the deposition of hydrocarbon polymer on the scanned area is reduced or eliminated resulting in better measurements. Another result of cleaner specimen chambers is that the condensation and adsorption of hydrocarbons on detector windows is reduced which allows the passage of more low energy x-rays and electrons through these windows.

### SUMMARY OF THE INVENTION

An improved method and apparatus for oxidative cleaning the specimen chamber, the specimen, and the specimen stage of electron microscopes and other charged beam instruments are disclosed. The invention covers the use of a UV light lamp with UV wavelengths below 193 nm, that disassociates oxygen, with an oxygen containing gas flowing past the UV lamp to form an Oxygen radical source that may be mounted on a port of the specimen chamber of the electron microscope. The oxygen radicals flow from the source through the chamber to the pumps and remove hydrocarbons by oxidation. The invention also covers the operation and design of the UV activated oxygen radical source in such a way that allows it to generate oxygen radicals from air and other nitrogen/oxygen mixtures without the production of ions and free electrons. The oxygen radicals are used for cleaning the interior walls and surfaces, specimen stage and specimen. The invention also covers a control method and arrangement for operating the evacuation system of the electron microscope, the UV source, and the admission of gas into the chamber.

### BRIEF DESCRIPTION OF DRAWINGS

The present invention together with the above and other objects and advantages may best be understood from the following detailed description of the preferred embodiments of the invention illustrated in the drawing, wherein:

FIG. 1 is a diagram of a typical scanning electron microscope (SEM) and accessories with an apparatus to implement the present invention installed.

FIG. 2 is a diagram of a control system for the present invention and its interaction with the SEM evacuation control system.

### REFERENCE NUMERALS IN DRAWINGS

1 Electron Gun
2 Electron Column
4 Vacuum Chamber
6 Specimen
8 Specimen Stage
10 X-ray Spectrometer
12 X-ray Detector and Window
14 Secondary Electron Detector
16 Final Aperture
18 Electron Beam
20 High Vacuum Pump
22 Roughing Pump
24 Foreline Pump
26 SEM Vacuum-Sequence Controller
30 High Vacuum Valve
32 Roughing Valve
34 Foreline Valve
36 Vent Valve
38 Vent Gas supply
42 Oxidative Gas Supply
44 Oxidative Gas Control Valve
46 Vacuum Gauge
50 UV Disassociation Chamber
51 UV lamp
52 Insulated-Vacuum Feedthrough
54 Power cable
56 UV Lamp Power Supply
60 Controller—UV Oxidative Cleaning

### DETAILED DESCRIPTION OF THE INVENTION

In accordance with the invention, a technique has been developed which allows simultaneous cleaning of the interior, a specimen, and a specimen stage of a scanning electron microscope which minimizes and in some cases eliminates hydrocarbon contamination and films from the surface of inorganic specimens during analysis by Scanning Electron Microscopes. The invention also has utility for other analytical instruments such as Transmission Electron Microscopes, Scanning Electron Microprobes, Focused Ion Beam and other charged particle beam instruments that have a vacuum environment and provide analytical information from emitted electrons and x-rays from the specimen. It also has utility for cleaning high vacuum chambers of any type where hydrocarbon removal is desired. The specimen need not be present during chamber and stage cleaning. The procedure, which involves subjecting the specimen chamber, specimen, and stage to oxygen radicals for oxidation and removal of hydrocarbons, is carried out prior to analysis. The oxygen radicals are generated by passing low-pressure air or other nitrogen and oxygen mixture by UV lamp that produces wavelengths below 240 nm and especially below 193 nm. The UV lamp is mounted inside an apparatus mounted on a chamber port on a vacuum chamber such as the specimen chamber of the electron microscope or similar electron beam instrument. The UV source is subject to the same vacuum as the chamber and is either within the chamber or in an extension of the chamber. Air or other Oxygen containing gas is supplied through at control valve to maintain low pressure below 133 Pa or 1 Torr while the chamber is being vacuum pumped. The gas flows from the source, past the UV lamp, through the SEM chamber and on to the vacuum pump, carrying the oxygen radicals to the Hydrocarbons that are to be destroyed and removed as the oxidized gases. The advantage of this arrangement is that the gas is carried past the most intense UV light beside the lamp and the active species are carried at almost full strength to the surfaces to be cleaned. This is preferable to the arrangement were UV light is projected on the surface to be cleaned and reactive gas is supplied at the spot to be cleaned because the intensity of the UV light is diminished by the cube of the distance from the source.

### Detailed Description of the Preferred Embodiments

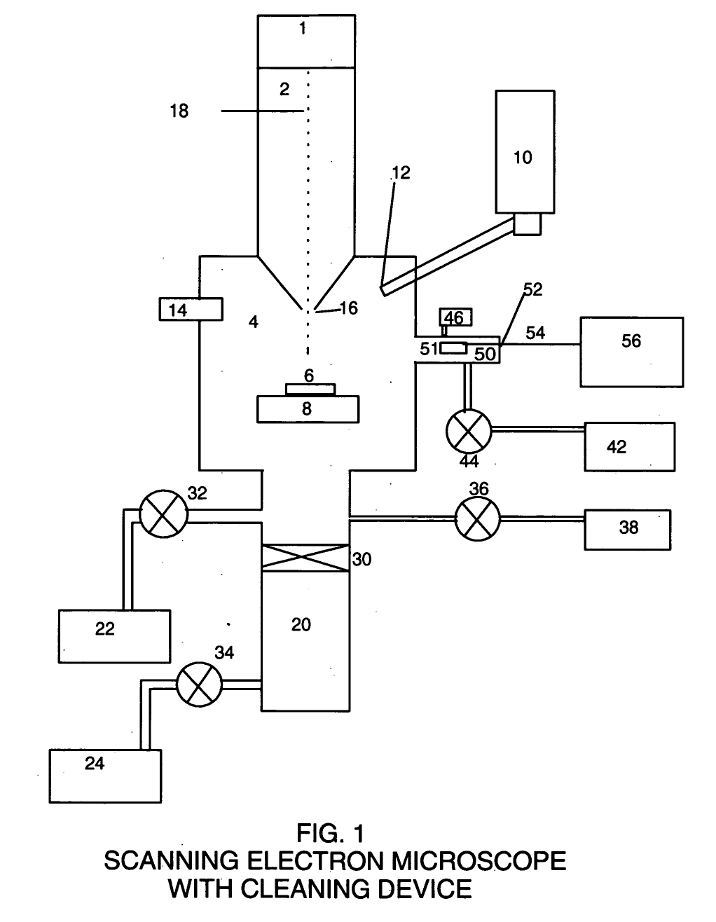

FIG. 1 is a schematic of a typical Scanning Electron Microscope (SEM) with the external UV cleaning device installed that employs the present method. Electron gun 1 generates electron beam 18, which is focused and scanned within electron column 2. The beam 18 exits through aperture 16 into specimen chamber 4 and scans across specimen 6. The specimen 6 is mounted on stage 8. The stage 8 usually can be manipulated to mechanically locate the specimen under the beam 18. The specimen 6 emits electrons and x-rays when scanned and a variety of detectors may be used to obtain analytical information. The most important of these are secondary electron detector 14 and Energy Dispersive (EDS) x-ray detector with a x-ray spectrometer 10. The x-ray detector is separated from the specimen chamber 4 by a x-ray window 12.

Electron scanning for microscopy is done under vacuum conditions. Typically the specimen or vacuum chamber 4 is connected to high vacuum pump 20 thorough valve 30. Foreline pump 24 is used to pump the exhaust of the high vacuum pump 20. Valve 34 separates the high vacuum pump and foreline pump. Pre-evacuation or roughing the chamber 4 is done by means of roughing pump 22 that connects to the chamber 4 by way of roughing valve 32. In evacuation of the chamber 4, a rough vacuum must be obtained first before the high vacuum pump 20 can function. In some arrangements of SEMs, the functions of foreline pump 24 and the roughing pump 22 are combined through means of a valving system so that only one low vacuum pump is needed for both functions. Venting of the chamber 4 takes place through vent valve 36 using vent gas supply 38 or air. All modern SEM models provide automatic valve sequencing controller 26 to simplify evacuation of the microscope for the user. For most models the user interface consists of a VENT and EVAC or similar push-button control provided as real buttons or on a computer screen.

The first embodiment of the present invention method uses a chamber 50 with an interior UV lamp 51. The UV lamp 51 is connected to a power supply 56 through cable 54 and insulated vacuum feedthrough 52 connected to the UV lamp 51. The output of UV lamp power supply 56 controls the power and the temperature of the UV lamp 51. The preferred UV wavelengths are between 193 nm and 150 nm and between 240 nm and 220 nm. At the preferred operating UV wavelengths and pressures of the present method, the Oxygen radicals are produced that flow into the Specimen chamber 4. The UV light may optionally be allowed to enter chamber 4 to activate the hydrocarbons for oxidation. The method of the present invention limits the wavelengths of the UV source so that Nitrogen is not disassociated or ionized, and limits the pressure to below 133 Pa or 1 Torr so that the Oxygen radicals do not react with air molecules to form O3 (Ozone) or N20 molecules by means of three body collisions in significant quantities.

In the preferred embodiment of the present invention shown in FIG. 1 the reactive gas is fed through UV disassociation chamber 50. Reactive gas supply 42 supplies the reactive Oxygen gas mixture gas for disassociation. In the preferred embodiment of the present invention this reactive gas is air. The reactive gas may be pure oxygen or any gas mixture containing molecular oxygen or oxygen compounds. Nitrogen/oxygen gas mixtures that contain 15%-30% oxygen are good choices for preferential removal of hydrocarbon films. A high percentage (>50%) oxygen mixture is avoided because of the explosion hazard in the vacuum pumps 22 and 24 if they are oil sealed rather than dry pumps. Valve 44 controls the reactive gas flow into the glow discharge and onto chamber 4. By the method of the preferred embodiment of the present invention the reactive gas is fed directly into the chamber 50, and oxygen radicals flow into the chamber 4 by convection provided by the pumping differential to the roughing pump 22. Pressure gauge 46 is used to monitor the chamber vacuum during cleaning and may mounted on the UV chamber 50 or chamber 4. The present invention uses a chamber pressure below 1 Torr. The present invention uses the oxygen radicals to oxidize the hydrocarbon contaminants to clean the specimen chamber walls, specimen, and specimen stage to form volatile oxide gases such as CO, CO₂, and H₂O that are carried to the roughing pump 22 by convective flow.

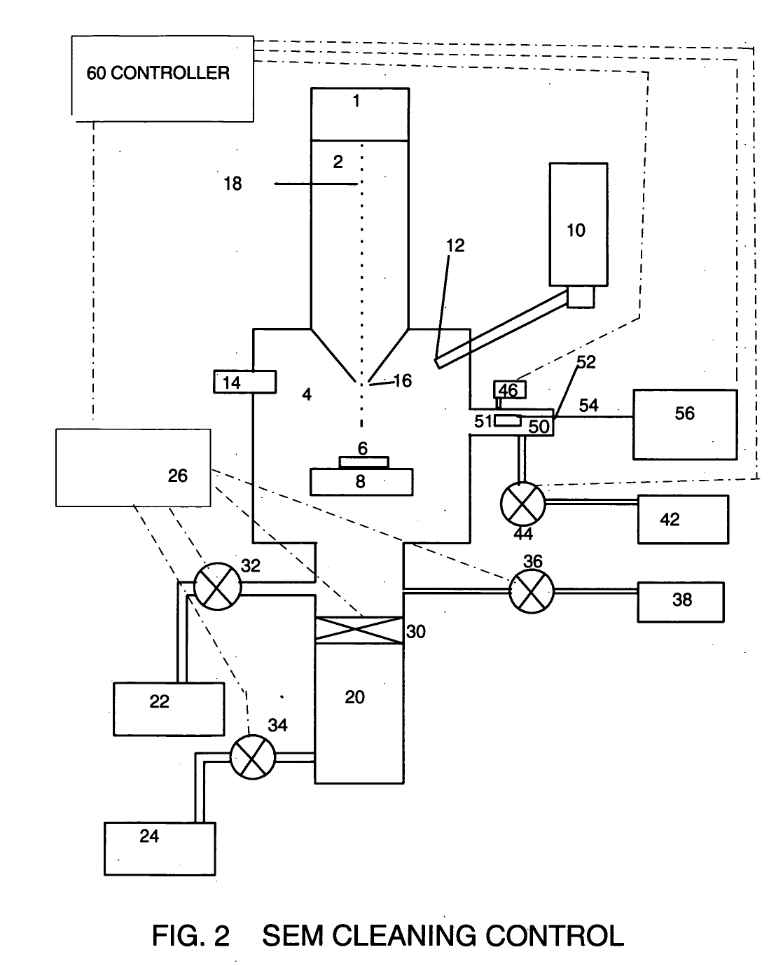

FIG. 2 illustrates a control arrangement for the present invention. Controller 60 may be connected to the SEM vacuum sequence controller 26 to start the vent and evacuation cycles. The Controller 60 operates valve 44 to admit air, monitors the vacuum though gauge 46, and operates the RF or DC generator 56 in a predetermined and timed sequence. As an alternative control method, the Controller 60 has no direct connection to the valve sequence controller 26 and uses the changes in pressure as sensed by vacuum gauge 46 to determine when to start the cleaning sequence. In this alternative, cleaning is initiated by the operator venting the chamber to pressure above one Torr and then restarting the evacuation system. When the pressure drops to a preset level the flow of oxidative gas is started by opening valve 44 and turning on the UV lamp 51.

### Operation

The first embodiment of the method employs the following operating sequence to clean the chamber:
1. Partially vent the chamber 4 using vent gas 38.
2. When the pressure is above one Torr, restart evacuation
3. Open valve 44 and admit reactive gas 42 into chamber 50. The reactive gas is air or any gas or mixture containing oxygen.
4. The UV source may be operated when the pressure is below 1 Torr.
5. At a pre-selected pressure turn on the UV lamp to produce radiation below 193 nm and above 50 nm wavelength.
6. At a predetermined time close valve 44 and let chambers 4 and 50 evacuate.
7. At a predetermined time stop oxygen radical cleaning by turning off the UV source.
8. As an option a purge gas of dry nitrogen may be admitted though either valve 44 or 36 to sweep away the remaining oxygen and oxidation product gases after the glow discharge is turned off.
9. Pump SEM down to operating pressure.

The sequence may be repeated, if further cleaning is needed.

The second embodiment of the invention follows the method described in the first embodiment and uses a Hg Vapor lamp as the UV light source 51. The Hg resonance lamp that emits light at 185 nm. Said wavelength will disassociate Oxygen with 100% of the light at 185 nm producing O radicals. Hg lamps produce most of their output at 254 nm, but with some radiation at 185 nm. This UV light is not absorbed by Nitrogen molecules.

The third embodiment of the invention follows the method described in the first embodiment and uses a Xe excimer lamp as the UV lamp 51. The Xe lamp produces radiation that peaks at 172 nm which disassociates O2 into O radicals at high efficiency but is not absorbed by Nitrogen molecules.

In the fourth embodiment of the invention the UV source is located within the specimen chamber and irradiates said chamber while the Oxygen containing gas flows through the region of the UV source.

While the present embodiments of the invention are described, it is to be distinctly understood that the invention is not limited thereto but may be otherwise embodied and practiced within the scope of the following claims.

I claim:

1. A method for cleaning and removing hydrocarbons in vacuum systems including those in a Scanning Electron Microscope, Transmission Electron Microscope, Scanning Electron Microprobe or other charged particle beam instrument by generating oxygen radicals from air, pure oxygen, or and any oxygen containing gas mixtures including but not limited to oxygen/nitrogen, oxygen/argon and oxygen/helium mixtures under the vacuum conditions produced within said instrument, comprising the steps of:
a) providing a UV light means for photo disassociation of oxygen molecules to oxygen radicals,
b) said UV light being a wavelength below 193 nm,
c) said UV means being a lamp enclosed in a material transparent to the desired UV wavelengths,
d) said vacuum being a pressure below 1 Torr to minimize the production of ozone, and
e) flowing said oxygen radicals from the region of said UV lamp to the area to cleaned such that said oxygen radicals are used to oxidize said hydrocarbons for removal.

2. A method for cleaning and removing hydrocarbons in vacuum systems as described in claim 1, further including the step of providing a photo disassociation chamber to contain said UV lamp connected to the vacuum chamber of said instruments.

3. A method for cleaning and removing hydrocarbons in vacuum systems as described in claim 1, further including the step of providing a means of introducing air or other oxygen gas mixtures directly into said region of said UV lamp.

4. A method for cleaning and removing hydrocarbons in vacuum systems as described in claim 1, further including the step of providing a vacuum gauge means and a gas regulating system means to regulate introduction of a gas into said instrument's vacuum chamber to achieve a desired pressure.

5. A method for cleaning and removing hydrocarbons in vacuum systems as described in claim 1, further including the step of controlling the pressure within said vacuum chamber to between 1 Torr and 10⁻⁶ Torr.

6. A method for cleaning and removing hydrocarbons in vacuum systems as described in claim 1, further including the step of using the means of venting and evacuation of said chamber provided by said vacuum system to partially backfill said specimen chamber with gas and then to re-evacuate said chamber.

7. A method for cleaning and removing hydrocarbons in vacuum systems as described in claim 4 further including the step of employing a controller apparatus means to monitor said chamber vacuum pressure, said gas introduction, said gas mixture, said pressure, and said UV light power according to a predetermined sequence.

8. A method for cleaning and removing hydrocarbons in vacuum systems as described in claim 1 further including the step of using pressure low enough for simultaneous charged particle beam operation during the time said oxygen radicals are being produced.

9. Apparatus for cleaning and removing hydrocarbons in vacuum systems such as a Scanning Electron-Microscope, Analytical Electron Microscope, Scanning Electron Microprobe or other charged particle beam instrument by generating oxygen radicals from air or other nitrogen/oxygen gas mixtures under vacuum conditions comprising
a means of flowing the gas mixture past a UV lamp,
said UV lamp produces wave lengths between 193 nm and 150 nm that disassociates oxygen molecules,
said vacuum conditions being pressures between 1 Torr and 10⁻⁶ Torr such that ozone is not created in significant quantities,
a means for flowing said radicals from said UV lamp to the region to be cleaned in said vacuum system,
and a means of controlling the pressure in said vacuum system by adjusting the input flow rate of said gas past said UV lamp,
such that said oxygen radicals are used to remove hydrocarbon contaminants by oxidation.

10. Apparatus for cleaning and removing hydrocarbons in vacuum systems as described in claim 9 with said UV lamp being inside a chamber connected either outside or inside the vacuum chamber of said instrument.

11. Apparatus for cleaning and removing hydrocarbons in vacuum systems as described in claim 9 combined with a means of introducing air or other nitrogen/oxygen gas mixtures directly into said UV lamp region.

12. Apparatus for cleaning and removing hydrocarbons in vacuum systems as described in claim 9 combined with a vacuum gauge means and a gas regulating system means to regulate the introduction of said gas mixtures into said vacuum system.

13. Apparatus for cleaning and removing hydrocarbons in vacuum systems as described in claim 9 combined a controller apparatus means that monitors said chamber vacuum and controls any of the following: venting, evacuation, gas flow, gas mixture, pressure, and UV means power according to a predetermined sequence.

14. Apparatus for cleaning and removing hydrocarbons in vacuum systems as described in claim 9 that uses the means of venting and evacuation said specimen chamber of said analytical instrument to partially backfill said specimen chamber with a gas and then to re-evacuate said chamber.
